(19) United States
(12) Patent Application Publication
(10) Pub. No.: US 2010/0134336 A1
(43) Pub. Date: Jun. 3, 2010

(54) CODEC PLATFORM APPARATUS

(76) Inventors: Jong Mo SUNG, Daejeon (KR); Hyun Joo BAE, Daejeon (KR); Byung Sun LEE, Daejeon (KR)

Correspondence Address: LADAS & PARRY LLP, 224 SOUTH MICHIGAN AVENUE, SUITE 1600, CHICAGO, IL, 60604, US

(21) Appl. No.: 12/556,058

(22) Filed: Sep. 9, 2009

(30) Foreign Application Priority Data
Dec. 2, 2008 (KR) 10-2008-0121393

(51) Int. Cl. H03M 1/66; H03M 1/12

(52) U.S. Cl. 341/144; 341/155

(57) ABSTRACT

A codec platform apparatus which can perform encoding or decoding regardless of a sampling frequency supported by a codec platform is provided. The codec platform apparatus includes an analog-to-digital converter (ADC) converting an analog input signal into a digital signal by sampling the analog input signal at a codec platform sampling frequency; a sampling frequency converter converting the digital signal provided by the ADC into a digital signal having a codec sampling frequency; and an encoder generating a bit stream by compressing the digital signal provided by the sampling frequency converter. Since there is no need to adopt a new codec platform even when an existing codec platform does not support the sampling frequency of a new codec, there is no need to implant the new codec. Therefore, it is possible to improve user satisfaction.

### CROSS-REFERENCE TO RELATED APPLICATION

This application claims priority from Korean Patent Application No. 10-2008-0121393, filed on Dec. 2, 2008 in the Korean Intellectual Property Office, the disclosure of which is incorporated herein by reference in its entirety.

### BACKGROUND OF THE INVENTION

1. Field of the Invention

The present invention relates to a codec platform apparatus, and more particularly, to a codec platform apparatus which can convert a digital signal having a codec platform sampling frequency into a digital signal having a codec sampling frequency and vice versa.

2. Description of the Related Art

Codecs are devices for encoding or decoding signals. Audio codec technology for encoding audio signals or decoding audio signals has been widely used in various fields such as wired communication (such as a public switched telephone network (PSTN)), mobile and Internet telecommunication (such as Voice over Internet Protocol (VoIP)), portable devices (such as an MP3 player), streaming, digital video discs (DVDs), and high-definition televisions (HDTVs). If an analog audio signal is sampled only using a predefined sampling frequency and the sampled audio signal is digitalized, the bit rate may considerably increase. Thus, this type of method may not be suitable for use in the field of devices with a low storage capacity and low bandwidth. For example, if an audio signal is sampled at a frequency of 8 kHz and is quantized with 16 bits per sample, a bit rate of 128000 bps may be obtained. Most audio communication networks adopt a codec apparatus for encoding and decoding audio signals in order to effectively transmit audio signals at low bit rate. There are various methods of encoding and decoding audio signals such as pulse code modulation (PCM) or code-excited linear prediction (CELP). Conventional audio codecs generally use a narrow bandwidth of 300 Hz to 3400 Hz, which is the same as the bandwidth of a telecommunication network. However, as the bandwidth of networks increases and the demand for high-quality audio data rapidly grows, various audio codecs capable of processing audio signals with a wide bandwidth of 50 Hz to 7000 Hz, an super wide bandwidth of 50 Hz to 14000 Hz, or even a full bandwidth of 20 Hz to 20000 Hz have recently been developed and standardized.

An audio codec may be implanted into various types of terminal devices by being optimized for a certain platform. The certain platform may be ported into a special-purpose processor such as a digital signal processor (DSP) or a general-purpose processor such as a personal computer (PC). FIG. 1 illustrates a block diagram of a typical codec platform apparatus 100. Referring to FIG. 1, the codec platform apparatus 100 may include an analog-to-digital converter (ADC) 104, an encoder 106, a decoder 108 and a digital-to-analog converter (DAC) 110. The codec platform apparatus 100 may be connected to a microphone 102 and a speaker 112. The microphone 102 and the speaker 112 may be embedded in the codec platform apparatus 100. The codec platform apparatus 100 may perform both an encoding operation, which is characterized by compressing an input signal into a bit stream, and a decoding operation, which is characterized by restoring a signal from an input bit stream.

The encoding operation will hereinafter be described in detail. The microphone 102 may receive an analog input signal (such as an audio signal). The ADC 104 may convert the analog input signal into a digital signal by sampling the analog input signal at a codec platform sampling frequency fᵢₒ. The encoder 106 may generate a bit stream by compressing the digital signal, and may output the bit stream.

The decoding operation will hereinafter be described in detail. The decoder 108 may decode an input bit stream and may thus restore a digital signal from the input bit stream. The DAC 110 may convert the digital signal into an analog signal and may output the analog signal through the speaker 112. The sampling frequency fᵢₒ supported by the ADC 104 and the DAC 110 must be the same as a sampling frequency f_{codec} supported by a codec having the encoder 106 and the decoder 108. Thus, once a codec is determined, a codec platform having the same sampling frequency as that supported by the codec must be used. For example, an audio-application platform supporting sampling frequencies of 8 kHz, 11.025 kHz, 22.05 kHz, and 44.1 kHz may not be able to provide a sampling frequency of 16 kHz, which is a requisite for providing broadband audio services.

Therefore, when a codec platform sampling frequency and a codec sampling frequency are different, it is necessary to adopt a new codec platform supporting the codec sampling frequency and to port an existing codec into the new codec platform.

### SUMMARY OF THE INVENTION

The present invention provides a codec platform apparatus which can improve user satisfaction simply by converting a digital signal having a codec platform sampling frequency into a digital signal having a codec sampling frequency and vice versa without the need to adopt a new codec platform or port an existing codec into a new codec platform.

According to an aspect of the present invention, there is provided a codec platform apparatus including an analog-to-digital converter (ADC) converting an analog input signal into a digital signal by sampling the analog input signal at a codec platform sampling frequency; a sampling frequency converter converting the digital signal provided by the ADC into a digital signal having a codec sampling frequency; and an encoder generating a bit stream by compressing the digital signal provided by the sampling frequency converter.

According to another aspect of the present invention, there is provided a codec platform apparatus including a decoder decoding a digital signal having a codec sampling frequency from an input bit stream; a sampling frequency converter converting the decoded digital signal into a digital signal having a codec platform sampling frequency; and a digital-to-analog converter (DAC) converting the digital signal provided by the sampling frequency converter into an analog signal.

According to the present invention, it is possible to improve user satisfaction simply by converting a digital signal having a codec platform sampling frequency into a digital signal having a codec sampling frequency and vice versa without the need to adopt a new codec platform or port an existing codec into a new codec platform.

### BRIEF DESCRIPTION OF THE DRAWINGS

The above and other features and advantages of the present invention will become more apparent by describing in detail preferred embodiments thereof with reference to the attached drawings in which:

FIG. 1 illustrates a block diagram of a typical codec platform apparatus;

FIG. 2 illustrates a block diagram of a codec platform apparatus according to an exemplary embodiment of the present invention;

FIG. 3 illustrates a block diagram of an encoding sampling frequency converter shown in FIG. 2; and

FIG. 4 illustrates a block diagram of a decoding sampling frequency converter shown in FIG. 2.

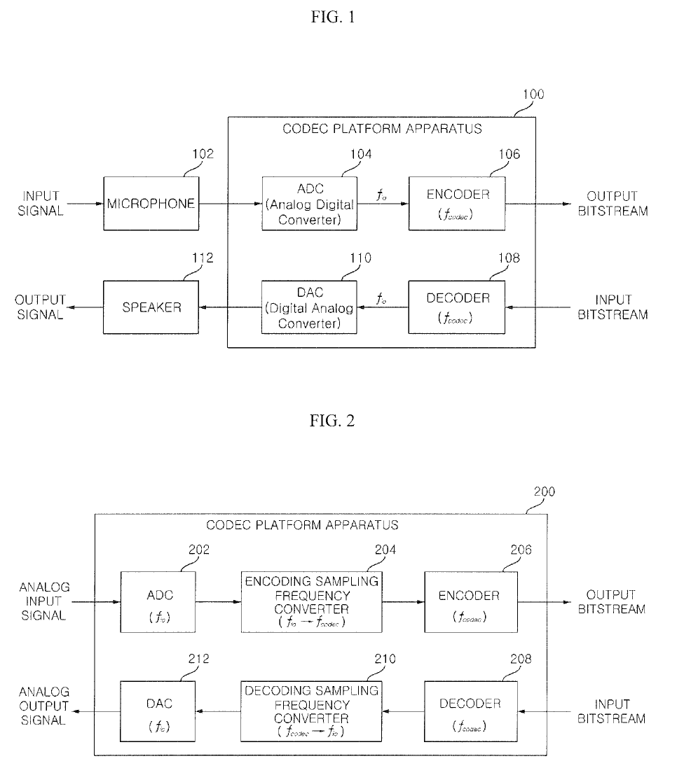

### DETAILED DESCRIPTION OF THE INVENTION

The present invention will hereinafter be described in detail with reference to the accompanying drawings in which exemplary embodiments of the invention are shown.

FIG. 2 illustrates a block diagram of a codec platform apparatus 200 according to an exemplary embodiment of the present invention. Referring to FIG. 2, the codec platform apparatus 200 may include an analog-to-digital converter (ADC) 202, an encoding sampling frequency converter 204, an encoder 206, a decoder 208, a decoding sampling frequency converter 210 and a DAC 212.

The ADC 202 may convert an analog input signal into a digital signal by sampling the analog input signal at a codec platform sampling frequency fᵢₒ.

The encoding sampling frequency converter 204 may convert the digital signal provided by the ADC 202 into a digital signal having a codec sampling frequency f_{codec}.

The encoder 206 may generate a bit stream by compressing the digital signal having the codec sampling frequency f_{codec}, and may output the bit stream.

The decoder 208 may decode a digital signal having the codec sampling frequency f_{codec} from an input bit stream.

The decoding sampling frequency converter 210 may convert the decoded digital signal into a digital signal having the codec platform sampling frequency fᵢₒ.

The DAC 212 may convert the digital signal provided by the decoding sampling frequency converter 210 into an analog signal.

An encoding operation performed by the codec platform apparatus 200 will hereinafter be described in further detail.

The ADC 202 may convert an analog input signal into a digital signal sampled at a sampling frequency supported by the ADC 202, i.e., the codec platform sampling frequency fᵢₒ. The encoding sampling frequency converter 204 may convert the digital signal provided by the ADC into a digital signal having the codec sampling frequency f_{codec}. The encoder 206 may generate a bit stream by compressing the digital signal having the codec sampling frequency f_{codec}.

A decoding operation performed by the codec platform apparatus 200 will hereinafter be described in further detail.

The decoder 208 may decode a digital signal having the codec sampling frequency f_{codec} from an input bit stream. The decoding sampling frequency converter 210 may convert the decoded digital signal into a digital signal having a sampling frequency supported by the DAC 212, i.e., the codec platform sampling frequency fᵢₒ. The DAC 212 may convert the digital signal provided by the decoding sampling frequency converter 210 into an analog signal and may output the analog signal.

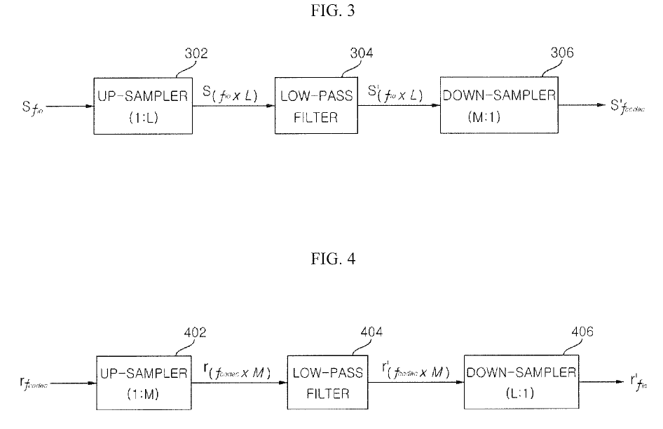

FIG. 3 illustrates a block diagram of the encoding sampling frequency converter 204 shown in FIG. 2. Referring to FIG. 3, the encoding sampling frequency converter 204 may include an up-sampler 302, a low-pass filter 304, and a down-sampler 306.

The up-sampler 302 may up-sample a digital signal sampled at the codec platform sampling frequency fᵢₒ by an up-sampling factor.

More specifically, the up-sampler 302 may perform up-sampling by inserting a number of zero samples corresponding to a value obtained by subtracting 1 from the up-sampling factor L for each sampling period into the digital signal sampled at the codec platform sampling frequency fᵢₒ.

The low-pass filter 304 may remove aliasing components, if any, caused by up-sampling performed by the up-sampler 302 or down-sampling performed by the down-sampler 306. The low-pass filter 304 may use a predefined cutoff frequency to remove such aliasing components. The predefined cutoff frequency may be whichever of a cutoff frequency for up-sampling and a cutoff frequency for down-sampling is lower than the other.

In short, the low-pass filter 304 may remove aliasing components, which may be generated by up-sampling or down-sampling and may cause signal distortions.

The down-sampler 306 may down-sample a signal provided by the low-pass filter 304 by a down-sampling factor in order to comply with the codec sampling frequency f_{codec}.

More specifically, the down-sampler 306 may perform down-sampling by extracting samples from the signal provided by the low-pass filter 304 at intervals of the down-sample factor.

The conversion of a signal having the codec platform sampling frequency fᵢₒ into a signal having the codec sampling frequency f_{codec} will hereinafter be described in detail.

The up-sampler 302 may convert an input signal having the codec platform sampling frequency fᵢₒ into an up-sampled signal s_{(fio×L)} having a sampling frequency L times higher than the codec platform sampling frequency fᵢₒ.

Thereafter, the low-pass filter 304 may remove aliasing components, if any, from the up-sampled signal s_{(fio×L)}, and may output a signal s′_{(fio×L)} obtained by the removal. A cutoff frequency ω_{c} of the low-pass filter 304 may be determined by Equation (1):

ω_{c}=min(π/L,π/M) (1).

where L and M are constants. The cutoff frequency ω_{c} may be a normalized frequency with the range of 0 and 1.

Thereafter, the down-sampler 306 may convert the signal s′_{(fio×L)} into a signal s′_{fcodec} having the codec sampling frequency f_{codec}. The constants L and M may be integers and may be determined by the ratio of the codec platform sampling frequency fᵢₒ and the codec sampling frequency f_{codec}.

For example, if the codec platform sampling frequency fᵢₒ and the codec sampling frequency f_{codec} are 32 kHz and 24 kHz, respectively, ( 24/32)=(¾)=(L/M), and thus, the up-sample factor (i.e., the constant L) and the down-sample factor (i.e., the constant M) may be 3 and 4, respectively.

In order to prevent the loss of an input signal, it is necessary to choose whichever of a plurality of sampling frequencies supported by a codec platform is higher than the sampling frequency of a codec.

FIG. 4 illustrates a block diagram of the decoding sampling frequency converter 210 shown in FIG. 2. Referring to FIG. 4, the decoding sampling frequency converter 210 may include an up-sampler 402, a low-pass filter 404 and a down-sampler 406.

The up-sampler 402 may up-sample a digital signal sampled at the codec sampling frequency f_{codec} by an up-sampling factor.

More specifically, the up-sampler 402 may perform up-sampling by inserting a number of zero samples corresponding to a value obtained by subtracting 1 from the up-sampling factor for each sampling period into the digital signal sampled at the codec platform sampling frequency f_{codec}.

The low-pass filter 404 may remove aliasing components, if any, caused by up-sampling performed by the up-sampler 402 or down-sampling performed by the down-sampler 406. The low-pass filter 404 may use a predefined cutoff frequency to remove such aliasing components. The predefined cutoff frequency may be whichever of a cutoff frequency for up-sampling and a cutoff frequency for down-sampling is lower than the other.

In short, the low-pass filter 404 may remove aliasing components, which may be generated by up-sampling or down-sampling and may cause signal distortions.

The down-sampler 406 may down-sample a signal provided by the low-pass filter 404 by a down-sampling factor in order to comply with the codec platform sampling frequency fᵢₒ.

More specifically, the down-sampler 406 may perform down-sampling by extracting samples from the signal provided by the low-pass filter 404 at intervals of the down-sample factor.

The conversion of a signal having the codec sampling frequency f_{codec} into a signal having the codec platform sampling frequency fᵢₒ will hereinafter be described in detail.

The up-sampler 402 may convert a decoded signal r_{fcodec} having the codec sampling frequency f_{codec} into an up-sampled signal r_{(fcodec×M)} having a sampling frequency M times higher than the codec sampling frequency f_{codec}.

Thereafter, the low-pass filter 404 may remove aliasing components, if any, from the up-sampled signal r_{(fcodec×M)}, and may output a signal r′_{(fcodec×M)} obtained by the removal.

Thereafter, the down-sampler 406 may convert the signal r′_{(fcodec×M)} into a signal r′_{fio} having the codec platform sampling frequency fᵢₒ. A cutoff frequency ω_{c} of the low-pass filter 404, like the cutoff frequency ω_{c} of the low-pass filter 304, may be determined by Equation (1). In addition, the up-sampling factor of the up-sampler 402 and the down-sampling factor of the down-sampler 406 may be determined using the same method used to determine the up-sampling factor of the up-sampler 302 and the down-sampling factor of the down-sampler 306. For example, if the codec platform sampling frequency fᵢₒ and the codec sampling frequency f_{codec} are 32 kHz and 24 kHz, respectively, the up-sampling factor (i.e., the constant M) of the up-sampler 402 and the down-sampling factor (i.e., the constant L) of the down-sampler 406 may be 4 and 3, respectively.

If the up-sampling factor of the up-sampler 302 or 402 and the down-sampling factor of the down-sampler 306 or 406 are 1, up-sampling and down-sampling may not be performed.

According to the present invention, it is possible to use even an audio codec having a sampling frequency not supported by an existing codec platform simply by adding a software program for converting a sampling frequency before an encoding or decoding operation.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A codec platform apparatus comprising:
an analog-to-digital converter (ADC) converting an analog input signal into a digital signal by sampling the analog input signal at a codec platform sampling frequency;
a sampling frequency converter converting the digital signal provided by the ADC into a digital signal having a codec sampling frequency; and
an encoder generating a bit stream by compressing the digital signal provided by the sampling frequency converter.

2. The codec platform apparatus of claim 1, wherein the sampling frequency converter comprises an up-sampler up-sampling the digital signal provided by the ADC by an up-sampling factor, a low-pass filter removing aliasing components caused by the up-sampling performed by the up-sampler and down-sampling performed by a down-sampler, and the down-sampler down-sampling a signal provided by the low-pass filter by a down-sampling factor so as to comply with the codec sampling frequency.

3. The codec platform apparatus of claim 2, wherein the up-sampler up-samples the digital signal provided by the ADC by inserting a number of zero samples corresponding to a value obtained by subtracting 1 from the up-sampling factor for each sampling period.

4. The codec platform apparatus of claim 2, wherein the down-sampler down-samples the signal provided by the low-pass filter by extracting samples from the signal provided by the low-pass filter at intervals of the down-sample factor.

5. The codec platform apparatus of claim 2, wherein the low-pass filter removes the aliasing components using whichever of a cutoff frequency for up-sampling and a cutoff frequency for down-sampling is lower than the other.

6. A codec platform apparatus comprising:
a decoder decoding a digital signal having a codec sampling frequency from an input bit stream;
a sampling frequency converter converting the decoded digital signal into a digital signal having a codec platform sampling frequency; and
a digital-to-analog converter (DAC) converting the digital signal provided by the sampling frequency converter into an analog signal.

7. The codec platform apparatus of claim 6, wherein the sampling frequency converter comprises an up-sampler up-sampling the decoded digital signal by an up-sampling factor, a low-pass filter removing aliasing components caused by the up-sampling performed by the up-sampler and down-sampling performed by a down-sampler, and the down-sampler down-sampling a signal provided by the low-pass filter by a down-sampling factor so as to comply with the codec platform sampling frequency.

8. The codec platform apparatus of claim 7, wherein the up-sampler up-samples the decoded digital signal by inserting a number of zero samples corresponding to a value obtained by subtracting 1 from the up-sampling factor for each sampling period.

9. The codec platform apparatus of claim 7, wherein the down-sampler down-samples the signal provided by the low-pass filter by extracting samples from the signal provided by the low-pass filter at intervals of the down-sample factor.

10. The codec platform apparatus of claim 7, wherein the low-pass filter removes the aliasing components using whichever of a cutoff frequency for up-sampling and a cutoff frequency for down-sampling is lower than the other.
